(19) United States
(12) Patent Application Publication
(10) Pub. No.: US 2024/0114750 A1
(43) Pub. Date: Apr. 4, 2024

(54) DISPLAY PANEL AND MANUFACTURING METHOD THEREOF, AND DISPLAY APPARATUS

(71) Applicants: Chengdu BOE Optoelectronics Technology Co., Ltd., Chengdu (CN); BOE Technology Group Co., Ltd., Beijing (CN)

(72) Inventors: Yuanjie XU, Beijing (CN); Wei ZHANG, Beijing (CN)

(21) Appl. No.: 17/769,179

(22) PCT Filed: Apr. 28, 2021
(86) PCT No.: PCT/CN2021/090536

§ 371 Date: Apr. 14, 2022

(51) Int. Cl. H10K 59/80

(52) U.S. Cl. CPC H10K 59/80518; H10K 71/621

(57) ABSTRACT

A display panel and a manufacturing method thereof, and a display apparatus are disclosed. The display panel has a display region, the display region including: a first display region and a second display region; light transmittance of the first display region is greater than light transmittance of the second display region; and the display panel includes: a substrate having a plurality of first sub-pixels located in the first display region; the plurality of first sub-pixels include a plurality of first anodes, and each of the first anodes includes: a first transparent conductive layer on the substrate, a first reflective layer on a side of the first transparent conductive layer away from the substrate, and a second transparent conductive layer on a side of the first reflective layer away from the substrate; the plurality of first anodes include at least one first-type first anode.

### FIELD

The disclosure relates to the field of display technology, and particularly to a display panel and a manufacturing method thereof, and a display apparatus.

### BACKGROUND

With high-speed development of a smartphone, an attractive appearance of the smartphone is required, and besides, more excellent visual experience needs to be brought to a smartphone user. Various manufacturers have started to increase a screen-to-body ratio of the smartphone, so a full screen becomes a new competition of the smartphone. With development of the full screen, there are increasing demands for improving performance and functions, a camera under panel can bring impact on visual and using experience to a certain degree on the premise of no influence on a high screen-to-body ratio.

### SUMMARY

In an aspect, an embodiment of the disclosure provides a display panel having a display region, the display region including: a first display region and a second display region; where light transmittance of the first display region is greater than light transmittance of the second display region; and the display panel includes: a substrate having a plurality of first sub-pixels located in the first display region; the plurality of first sub-pixels include a plurality of first anodes, and each of the first anodes includes: a first transparent conductive layer on the substrate, a first reflective layer on a side of the first transparent conductive layer away from the substrate, and a second transparent conductive layer on a side of the first reflective layer away from the substrate; where: the plurality of first anodes include at least one first-type first anode, and an orthographic projection area of a first transparent conductive layer in the first-type first anode on the substrate is larger than an orthographic projection area of a first reflective layer in the first-type first anode on the substrate.

Optionally, in the above display panel provided by an embodiment of the disclosure, orthographic projections of the first reflective layer and a second transparent conductive layer in the first-type first anode on the substrate substantially overlap.

Optionally, in the above display panel provided by an embodiment of the disclosure, the plurality of first anodes further includes a second-type first anode, and an orthographic projection area of a first transparent conductive layer in the second-type first anode on the substrate is larger than an orthographic projection area of a first reflective layer in the second-type first anode on the substrate; the first transparent conductive layer and the first reflective layer in the first-type first anode have a first non-overlapping region, the first transparent conductive layer and the first reflective layer in the second-type first anode have a second non-overlapping region, and an area of the first non-overlapping region is different from an area of the second non-overlapping region.

Optionally, in the above display panel provided by an embodiment of the disclosure, the area of the first non-overlapping region is larger than the area of the second non-overlapping region, and an area of the first reflective layer in the first-type first anode is smaller than an area of the first reflective layer in the second-type first anode.

Optionally, in the above display panel provided by an embodiment of the disclosure, the area of the first non-overlapping region is smaller than the area of the second non-overlapping region, and an area of the first reflective layer in the first-type first anode is larger than an area of the first reflective layer in the second-type first anode.

Optionally, in the above display panel provided by an embodiment of the disclosure, the plurality of first anodes further includes a second-type first anode, and orthographic projections of a first transparent conductive layer, a first reflective layer and a second transparent conductive layer in the second-type first anode on the substrate substantially overlap.

Optionally, in the above display panel provided by an embodiment of the disclosure, an orthographic projection area of the first transparent conductive layer in the first-type first anode on the substrate is larger than an orthographic projection area of the first transparent conductive layer in the second-type first anode on the substrate, and an orthographic projection area of the first reflective layer in the second-type first anode on the substrate is larger than an orthographic projection area of the first reflective layer in the first-type first anode on the substrate.

Optionally, in the above display panel provided by an embodiment of the disclosure, the first transparent conductive layer of the first anode includes a main body part and a connection line connected to the main body part, and an orthographic projection of the first reflective layer in the first-type first anode on the substrate falls into a range of an orthographic projection of a main body part in the first-type first anode on the substrate.

Optionally, in the above display panel provided by an embodiment of the disclosure, a center position of the first reflective layer in the first-type first anode substantially coincides with a center position of the main body part.

Optionally, in the above display panel provided by an embodiment of the disclosure, the plurality of first anodes include a plurality of first-type first anodes, the plurality of first anodes include a plurality of second-type first anodes, and all the first-type first anodes and all the second-type first anodes are uniformly distributed in the first display region.

Optionally, in the above display panel provided by an embodiment of the disclosure, the plurality of first anodes are distributed in an array, the first-type first anodes and the second-type first anodes are alternately arranged in a column direction, or the first-type first anodes and the second-type first anodes are alternately arranged in a row direction.

Optionally, the above display panel provided by an embodiment of the disclosure further includes a plurality of second sub-pixels located in the second display region, where each of the second sub-pixels is provided with a second anode, the second anode includes: a third transparent conductive layer on the substrate, a second reflective layer on a side of the third transparent conductive layer away from the substrate, and a fourth transparent conductive layer on a side of the second reflective layer away from the substrate; orthographic projections of the third transparent conductive layer, the second reflective layer and the fourth transparent conductive layer on the substrate substantially overlap.

Optionally, in the above display panel provided by an embodiment of the disclosure, the plurality of first sub-pixels have a plurality of emission colors, and the first-type first anode and the second-type first anode correspond to first sub-pixels with a same emission color.

Optionally, the above display panel provided by an embodiment of the disclosure further includes a plurality of second sub-pixels located in the second display region, where each of the second sub-pixels is provided with a second anode, the second anode includes: a third transparent conductive layer on the substrate, a second reflective layer on a side of the third transparent conductive layer away from the substrate, and a fourth transparent conductive layer on a side of the second reflective layer away from the substrate; a resolution of the first display region is less than a resolution of the second display region, and a ratio of an area of the second reflective layer in the second anode to an area of the first reflective layer in the first anode is in a range of 0.7 to 1.5.

Optionally, the above display panel provided by an embodiment of the disclosure further includes a plurality of second sub-pixels located in the second display region, where each of the second sub-pixels is provided with a second anode, the second anode includes: a third transparent conductive layer on the substrate, a second reflective layer on a side of the third transparent conductive layer away from the substrate, and a fourth transparent conductive layer on a side of the second reflective layer away from the substrate; a ratio of a resolution of the first display region to a resolution of the second display region is in a range of 0.8 to 1.2, and the second anode is larger than the first anode in size.

Optionally, the above display panel provided by an embodiment of the disclosure further includes a bezel region located outside the display region, and the display panel further includes a plurality of first driving circuits electrically connected to the first anodes, where the plurality of first driving circuits are located in the bezel region adjacent to the first display region; or the second display region has a transition region adjacent to the first display region, and the plurality of first driving circuits are located in the transition region, or the plurality of first driving circuits are distributed in the second display region.

Optionally, the above display panel provided by an embodiment of the disclosure further includes a transparent wire routing layer between the first driving circuits and the first anodes, where the first driving circuits are electrically connected to the first anodes through transparent wires in the transparent wire routing layer.

Optionally, in the above display panel provided by an embodiment of the disclosure, materials of the first transparent conductive layer, the second transparent conductive layer, the third transparent conductive layer and the fourth transparent conductive layer include at least one of ITO, IZO or IGZO, and materials of the first reflective layer and the second reflective layer include at least one of Al, Ag, Mo, Ti or TiN.

Optionally, in the above display panel provided by an embodiment of the disclosure, a shape of the first display region is at least one of a circle, an ellipse, a rectangle or a polygon.

In another aspect, an embodiment of the disclosure further provides a display apparatus, including a photosensitive device and the display panel described in any one of the above; where the photosensitive device is disposed in the first display region of the display panel.

In another aspect, an embodiment of the disclosure further provides a manufacturing method of a display panel, including: providing a substrate; where the substrate has a display region, the display region includes a first display region and a second display region; the substrate has a plurality of first sub-pixels located in the first display region; where light transmittance of the first display region is greater than light transmittance of the second display region; forming a plurality of first anodes in the first sub-pixels of the substrate; where each of the first anodes includes: a first transparent conductive layer on the substrate, a first reflective layer on a side of the first transparent conductive layer away from the substrate, and a second transparent conductive layer on a side of the first reflective layer away from the substrate; where: the plurality of first anodes include at least one first-type first anode, and an orthographic projection area of a first transparent conductive layer in the first-type first anode on the substrate is larger than an orthographic projection area of a first reflective layer in the first-type first anode on the substrate.

Optionally, in the above manufacturing method provided by an embodiment of the disclosure, forming the first-type first anode in a first sub-pixel of the substrate, includes: depositing a first conductive film on the substrate; where a material of the first conductive film includes at least one of ITO, IZO or IGZO; depositing a reflective conductive film on a side of the first conductive film away from the substrate; where a material of the reflective conductive film includes at least one of Al, Ag, Mo, Ti or TiN; depositing a second conductive film on a side of the reflective conductive film away from the substrate; where a material of the second conductive film includes at least one of ITO, IZO or IGZO; coating a first photoresist on a side of the second conductive film away from the substrate, and exposing and developing the first photoresist to form a first photoresist layer with a first width; etching away the second conductive film not covered by the first photoresist using a wet etching process, to form a second transparent conductive layer; etching away the reflective conductive film not covered by the second transparent conductive layer using a dry etching process, to form a first reflective layer; stripping the remaining first photoresist layer; coating a second photoresist on a side of the second transparent conductive layer away from the substrate, and exposing and developing the second photoresist to form a second photoresist layer with a second width; where the second width is greater than the first width; etching away the first conductive film not covered by the second photoresist using a wet etching process, to form a first transparent conductive layer; stripping the remaining second photoresist layer.

### BRIEF DESCRIPTION OF THE DRAWINGS

FIG. 1 is a structural schematic diagram of a top view of a display panel in the related art;

FIG. 2 is a structural schematic diagram of a display panel according to an embodiment of the disclosure;

FIG. 3 is a structural schematic diagram of another display panel according to an embodiment of the disclosure;

FIG. 4 is a cross-sectional schematic diagram of a second-type first anode;

FIG. 5 is a cross-sectional schematic diagram of a first-type first anode;

FIG. 6 is a cross-sectional schematic diagram of a second-type first anode;

FIG. 7 is a cross-sectional schematic diagram of a third anode;

FIG. 8 is a schematic diagram of a first transparent conductive layer in a first display region and a third transparent conductive layer in a second display region;

FIG. 9 is a theoretical schematic diagram of a first reflective layer in the first display region;

FIG. 10 is a schematic diagram of an actually fabricated first reflective layer in the first display region;

FIG. 11 is a cross-sectional schematic diagram of a transparent wire routing layer;

FIG. 12 is a schematic diagram of a simulation result capable of reducing diffraction according to an embodiment of the disclosure;

FIG. 13 is a schematic diagram of another simulation result capable of reducing diffraction according to an embodiment of the disclosure;

FIG. 14 is a schematic flowchart of a method for manufacturing a second-type first anode according to an embodiment of the disclosure;

FIGS. 15A-15L are cross-sectional schematic diagrams after performing each step in the method for manufacturing the second-type first anode according to an embodiment of the disclosure.

### DETAILED DESCRIPTION OF EMBODIMENTS

In order to make the purposes, schemes and advantages of the disclosure clearer, the schemes of embodiments of the disclosure will be described clearly and completely below in combination with the accompanying drawings of embodiments of the disclosure. Obviously the described embodiments are a part of embodiments of the disclosure but not all embodiments. Also in the case of no conflict, embodiments and the features therein in the disclosure can be combined with each other. Based upon embodiments of the disclosure, all of other embodiments obtained by those ordinary skilled in the art without creative work pertain to the protection scope of the disclosure.

Unless otherwise defined, the technical or scientific terms used in the disclosure shall have the general meaning understood by those ordinary skilled in the art to which the disclosure belongs. The word such as “include” or “contain” or the like used in the disclosure means that the element or object appearing before this word encompasses the elements or objects and their equivalents listed after this word, without excluding other elements or objects. The word such as “connect” or “connected” or the like is not limited to the physical or mechanical connection, but can include the electrical connection, whether direct or indirect. The words such as “inner”, “outer”, “up”, “down” are only used to represent the relative position relationship. When the absolute position of a described object changes, the relative position relationship may also change accordingly.

It is necessary to note that the size and shape of each diagram in the accompanying drawings do not reflect the true proportion, and are merely for purpose of schematically illustrating the content of the disclosure. Also, the same or similar reference numbers represent the same or similar elements or the elements having the same or similar functions all the way.

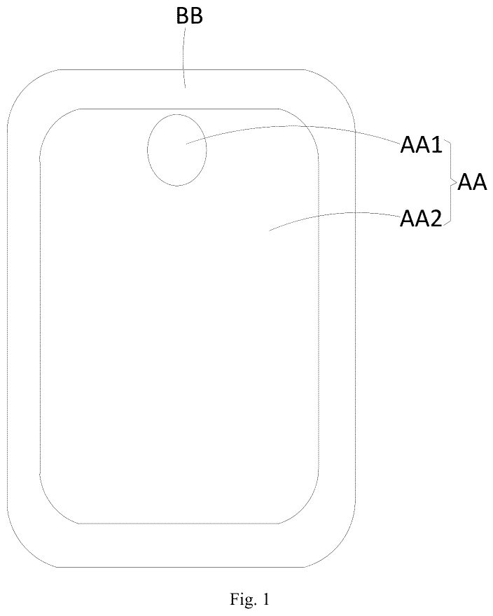

In the related art, as shown in FIG. 1, the camera under panel technology generally sets a first display region AA1 and a second display region AA2 in the display region AA. The second display region AA2 occupies most of the display region, the first display region AA1 occupies a smaller part of the display region, and the first display region AA1 is the position where the camera under panel is placed. The camera under panel means that a front camera is located below a screen but does not affect a display function of the screen. When the front camera is not used, the screen above the camera can still display images normally. Thus, from the appearance point of view, the camera under panel has no camera hole, achieving the full-screen display effect truly. However, in the current design scheme of the camera under panel, the pixel circuit of the first display region AA1 is arranged in a bezel region BB above the first display region AA1, the pixel circuit is connected to a light-emitting device in the first display region AA1 through a wire ITO, and the first display region AA1 only retains the light-emitting device. But the light emitted from the light-emitting device may diffract with the light reflected from a glass cover during shooting. According to the principle of coherence between crests and troughs, the light in certain areas will be strengthened. In the camera under panel area, the resulting phenomenon is that the light at certain angles is particularly strong, called star glare, which affects the photography quality.

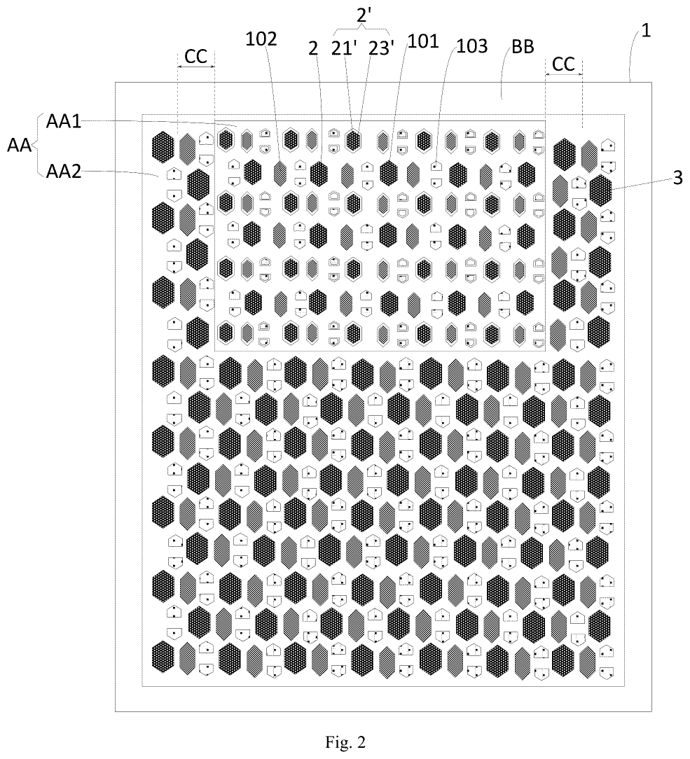

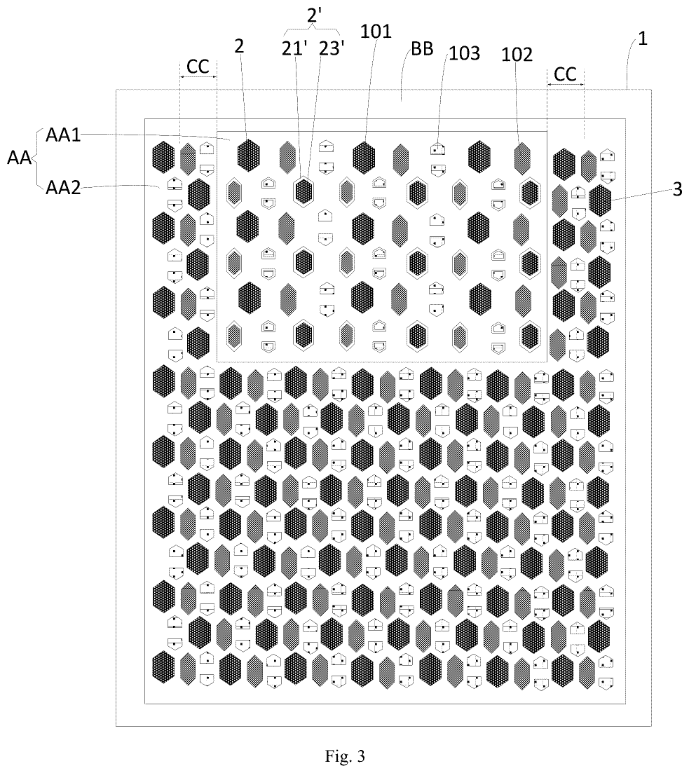

For the above technical problem existing in the related art, an embodiment of the disclosure provides a display panel, as shown in FIG. 2 and FIG. 3, the display panel has a display region AA, the display region AA includes: a first display region AA1 and a second display region AA2. Light transmittance of the first display region AA1 is greater than light transmittance of the second display region AA2. The display panel includes: a substrate 1 having a plurality of first sub-pixels located in the first display region AA1.

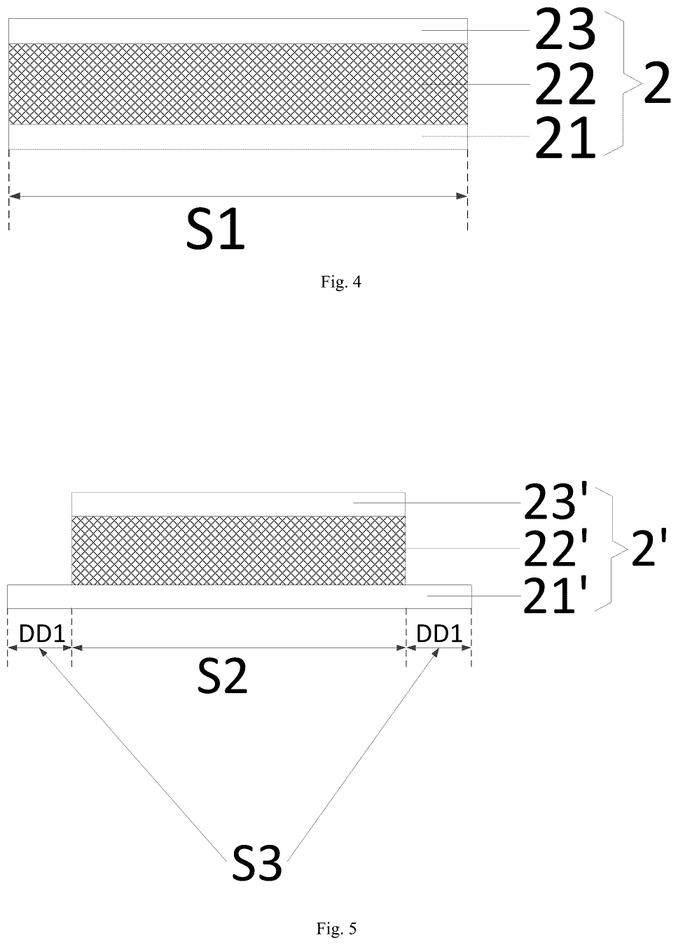

The plurality of first sub-pixels include a plurality of first anodes (2 and 2′). As shown in FIG. 4, the first anode (2) includes: a first transparent conductive layer 21 on the substrate 1, a first reflective layer 22 on a side of the first transparent conductive layer 21 away from the substrate 1, and a second transparent conductive layer 23 on a side of the first reflective layer 22 away from the substrate 1. As shown in FIG. 5, the first anode (2′) includes: a first transparent conductive layer 21′ on the substrate 1, a first reflective layer 22′ on a side of the first transparent conductive layer 21′ away from the substrate 1, and a second transparent conductive layer 23′ on a side of the first reflective layer 22′ away from the substrate 1.

As shown in FIG. 2 and FIG. 3, the plurality of first anodes include at least one first-type first anode 2′. As shown in FIG. 5, an orthographic projection area of the first transparent conductive layer 21′ in the first-type first anode 2′ on the substrate 1 is larger than an orthographic projection area of the first reflective layer 22′ in the first-type first anode 2′ on the substrate 1.

It should be noted that there are generally a plurality of sub-pixels in the display region, such as red (R) sub-pixels, green (G) sub-pixels and blue (B) sub-pixels. In order to solve the problem of sub-pixel life, for example, the Pentile sub-pixel arrangement is used. The Pentile arrangement chooses to reduce the number of red (R) and blue (B) sub-pixels by half. At the same time, in order to maintain the color accuracy in mixing three primary colors, the areas of these two types of sub-pixels are increased, and finally the brightnesses of these two types of sub-pixels are also reduced appropriately. The number of red (R) sub-pixels and blue (B) sub-pixels is approximately ½ of the number of green (G) sub-pixels.

As shown in FIGS. 2 and 3, the first anodes may include a first anode of a first sub-pixel 101 (e.g., B), a first anode of a second sub-pixel 102 (e.g., R), and a first anode of a third sub-pixel 103 (e.g., G). The first anodes of the first sub-pixel 101, the second sub-pixel 102 and the third sub-pixel 103 are not identical. Further, the first anode of the first sub-pixel 101 and the first anode of the second sub-pixel 102 have the same shape and different areas, and the first anode of the first sub-pixel 101 and the first anode of the second sub-pixel 102 are different from the first anode of the third sub-pixel 103 both in shape and area.

In the scheme of the camera under panel in the related art, the light emitted from the light-emitting device in the first display region AA1 may diffract with the light reflected from a glass cover during shooting. According to the principle of coherence between crests and troughs, the light in certain areas will be strengthened. In the camera under panel area, the resulting phenomenon is that the light at certain angles is particularly strong, called star glare, which affects the photography quality. The reason for such light diffraction is that the light transmittance of the first display region AA1 in the related art has a certain law, causing the strengthening effect of light in some specific directions and angles, so that the diffracted light is relatively strong, affecting the photography quality. Therefore, in the above display panel provided by an embodiment of the disclosure, at least one first-type first anode 2′ is arranged in the first display region AA1 (i.e., the position where the camera is placed), and the area of the reflective layer 22′ in the first-type the first anode 2′ is set to be smaller than the area of the first transparent conductive layer 21′, that is, the first-type first anode 2′ has a reflective light region and a transmissive light region, so that the first anodes 2 in the first display region AA1 may be set to be different structures, so the anodes with different structures in the first display region AA1 correspond to different light-emitting forms, and the center points and brightness distributions of the light-emitting formations are also different. Therefore, the arrangement of the first-type first anode 2′ in the first display region AA1 can destroy the regularity of the light transmitted through the first display region AA1, so that the phenomenon of strengthened light in some specific directions or points disappears, and the luminous brightness of parts other than the center point is reduced, thereby reducing diffraction, alleviating glare, and increasing the photography quality.

In a specific implementation, each film layer of the first-type first anode 2′ is formed using an etching process. In theory, it is possible to form the first reflective layer 22′ and the second transparent conductive layer 23′ with completely overlapping orthographic projections. But in some processes, due to different etching rates of the materials of layers, there may also be structures with incompletely overlapping edges, while this belongs to the process deviation of one etching. Therefore, in the above display panel provided by an embodiment of the disclosure, as shown in FIG. 5, the orthographic projections of the first reflective layer 22′ and the second transparent conductive layer 23′ in the first-type first anode 2′ on the substrate 1 substantially overlap, thereby forming the first-type first anode 2′ with a transmissive light region and a reflective light region.

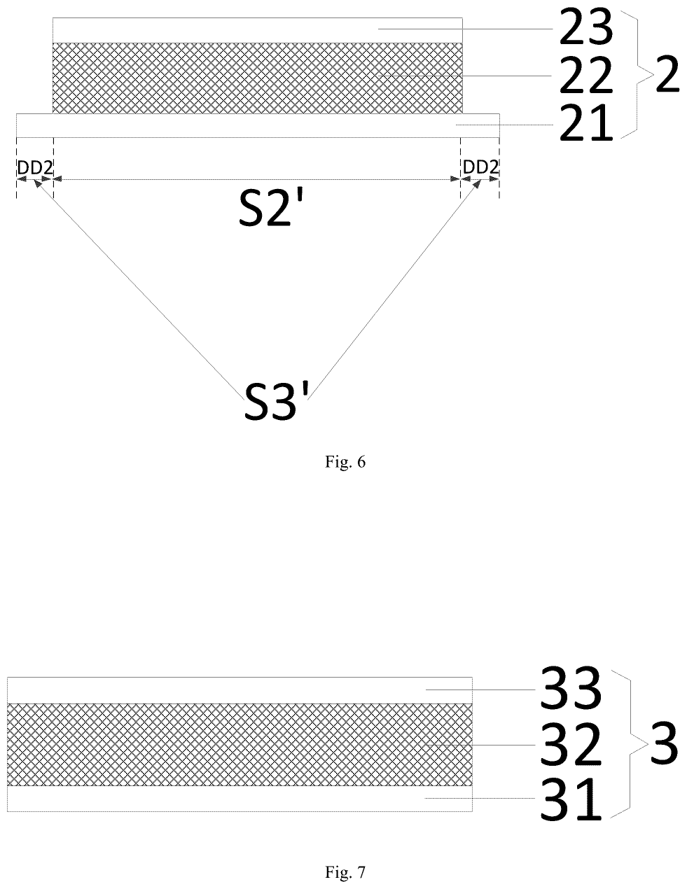

In a specific implementation, in the above display panel provided by an embodiment of the disclosure, as shown in FIG. 6, the plurality of first anodes further includes a second-type first anode 2. An orthographic projection area of a first transparent conductive layer 21 in the second-type first anode 2 on the substrate 1 is larger than an orthographic projection area of a first reflective layer 22 in the second-type first anode 2 on the substrate 1.

As shown in FIG. 5, the first transparent conductive layer 21′ and the first reflective layer 22′ in the first-type first anode 2′ have a first non-overlapping region DD. In some examples, since the planar shape of the first-type first anode 2′ may be different shapes, the corresponding first non-overlapping region DD1 may be of an annular shape surrounding the reflective layer 22′ of the first-type first anode 2′.

As shown in FIG. 6, the first transparent conductive layer 21 and the first reflective layer 22 in the second-type first anode 2 have a second non-overlapping region DD2. In some examples, since the planar shape of the second-type first anode 2 may be different shapes, the corresponding second non-overlapping region DD2 may be of an annular shape surrounding the reflective layer 22 of the second-type first anode 2. In some examples, the area of the first non-overlapping region DD1 is different from the area of the second non-overlapping region DD2. In some examples, both the first non-overlapping region DD1 and the second non-overlapping region DD2 are of annular shapes, and the radial dimension between the inner and outer rings of the annular shape of the first non-overlapping region DD1 is different from the radial dimension between the inner and outer rings of the annular shape of the second non-overlapping region DD2. In some examples, the contour of the first non-overlapping region DD1 may be substantially similar to that of the first-type first anode 2′. In some examples, the contour of the second non-overlapping region DD2 may be substantially similar to that of the second-type first anode 2. In this way, the first-type first anode 2′ shown in FIG. 5 and the second-type first anode 2 as shown in FIG. 6 can be formed in the first display region AA1, and the first-type first anode 2′ and the second-type first anode 2 have different structures, so that the regularity of the light transmitted through the first display region AA1 can be destroyed, the phenomenon of strengthened light in some specific directions or points disappears, and the luminous brightness of parts other than the center point is reduced, thereby reducing diffraction, alleviating glare, and increasing the photography quality. In some examples, the shape of the first non-overlapping region DD1 and the shape of the second non-overlapping region DD2 may be different, for example, one of the shape of the first non-overlapping region DD1 and the shape of the second non-overlapping region DD2 is a complete annular shape and the other is an incomplete annular shape, so that the first anodes exhibit different structures. In some examples, the reflective layer 22′ in the first-type first anode 2′ and the reflective layer 22 in the second-type first anode 2 may have different shapes or areas, so that the first anodes exhibit different structures.

In summary, in an embodiment of the disclosure, the first display region AA1 includes the first-type first anode 2′ and the second-type first anode 2, and structures of the first-type first anode 2′ and the second-type first anode 2 are different. Of course, the first display region AA1 may further include a third-type first anode, a fourth-type first anode, a fifth-type first anode, etc., as long as different first anode structures can be designed by changing the shape, size, thickness, etc. of each film layer of each type of first anode, and the original regularity of the light corresponding to the first anodes with the same structure in the first display region AA1 can be destroyed, so as to achieve the purpose of alleviating the glare. The structures of more types of first anodes will not be described in an embodiment of the disclosure.

Optionally, in an embodiment of the disclosure, the first-type first anode 2′ and the second-type first anode 2 with different structures and both having a reflective light region and a transmissive light region may be fabricated in the first display region AA1. As shown in FIG. 5 and FIG. 6, if the area of the first non-overlapping region DD1 is larger than that of the second non-overlapping region DD2, the luminous intensity of the sub-pixel corresponding to the first non-overlapping region DD1 is greater than the luminous intensity of the sub-pixel corresponding to the second non-overlapping region DD2. In order to ensure the uniform luminous brightness in the first display region AA1, the area of the first reflective layer 22′ in the first-type first anode 2′ shown in FIG. 5 should be made smaller than the area of the first reflective layer 22 in the second-type the first anode 2 shown in FIG. 6. Thus it can be ensured that the luminous brightness of the first display region AA1 is uniform.

Optionally, if the area of the first non-overlapping area can be smaller than the area of the second non-overlapping area, the area of the first reflective layer in the first-type first anode should be made larger than the area of the first reflective layer in the second-type first anode in order to ensure the uniform luminous brightness in the first display region AA1. In some examples, the first reflective layer in the first-type first anode and the first reflective layer in the second-type first anode may for example have the same shape but different areas. That is, FIG. 5 shows the structure of the first-type first anode, and FIG. 6 shows the structure of the second-type first anode.

In a specific implementation, in the above display panel provided by an embodiment of the disclosure, as shown in FIGS. 2, 3 and 4, the plurality of first anodes further includes a second-type first anode 2. Each film layer of the second-type first anode is formed using an etching process. In theory, the first transparent conductive layer 21, the first reflective layer 22 and the second transparent conductive layer 23 of which the orthographic projections are completely overlapped are formed. But in some processes, due to different etching rates of the materials of layers, there may also be structures with incompletely overlapping edges, while this belongs to the process deviation of one etching. Therefore, the orthographic projections of the first transparent conductive layer 21, the first reflective layer 22 and the second transparent conductive layer 23 on the substrate 1 substantially overlap.

Therefore, the first display region AA1 of the above display panel provided by an embodiment of the disclosure can simultaneously form the second-type first anode 2 shown in FIG. 4 and the first-type first anode 2′ shown in FIG. 5, or simultaneously form the first-type first anode 2′ shown in FIG. 5 and the second-type first anode 2 shown in FIG. 6, to break the regularity of the light transmitted through the first display region AA1, so that the phenomenon of strengthened light in some specific directions or points disappears, and the luminous brightness of parts other than the center point is reduced, thereby reducing diffraction, alleviating glare, and increasing the photography quality.

In a specific implementation, if the second-type first anode 2 shown in FIG. 4 and the first-type first anode 2′ shown in FIG. 5 are simultaneously formed in the first display region AA1, the first-type first anode 2′ shown in FIG. 5 has a reflective light region and a transmissive light region, and the size of the first reflective layer 22′ should be smaller than that of the first reflective layer 22 if the first transparent conductive layer 21′ and the first transparent conductive layer 21 have the same size, so the luminous intensities of the corresponding regions of the first-type first anode 2′ and the second-type first anode 2 are different. If the size of the first reflective layer 22′ is kept the same as the size of the first reflective layer 22, the size of the first transparent conductive layer 21′ should be larger than that of the first transparent conductive layer 21, so the luminous intensities of the corresponding regions of the first-type first anode 2′ and the second-type first anode 2 are also different. In order to ensure the uniform luminous brightness of the first display region AA1, in the above display panel provided by an embodiment of the disclosure, as shown in FIG. 4 and FIG. 5, the orthographic projection area of the first transparent conductive layer 21′ in the first-type first anode 2′ on the substrate 1 is larger than the orthographic projection area of the first transparent conductive layer 21 in the second-type first anode 2 on the substrate 1, and the orthographic projection area of the first reflective layer 22 in the second-type first anode 2 on the substrate 1 is larger than the orthographic projection area of the first reflective layer 22′ in the first type first anode 2′ on the substrate 1. For example, the luminous intensity of the region corresponding to the second-type first anode 2 is S1, the luminous intensity of the region corresponding to the first reflective layer 22′ in the first-type first anode 2′ is S2, and the luminous intensity corresponding to a region in the first transparent conductive layer 21′ that does not overlap with the first reflective layer 22′ (i.e., transmissive light region) is S3, then S3=S1−S2. Therefore, the size of the region in the first transparent conductive layer 21′ that does not overlap with the first reflective layer 22′ is adjusted so that S3=S1−S2. Therefore, the disclosure can achieve the uniform luminous brightness of the first display region AA1 on the basis of reducing diffraction, and does not affect the display quality on the basis of improving the photograph quality. In some examples, the ratio of S3 to (S1−S2) may be in a range of 0.7 to 1.5, and even a slight difference in brightness is not easily perceptible to the human eyes.

In a specific implementation, if the first-type first anode 2′ shown in FIG. 5 and the second-type first anode 2 shown in FIG. 6 are simultaneously formed in the first display region AA1, for example, the luminous intensity of the region corresponding to the first reflective layer 22 in the second-type first anode 2 shown in FIG. 6 is S2′, and the luminous intensity corresponding to a region in the first transparent conductive layer 21 that does not overlap with the first reflective layer 22 (i.e., transmissive light region) is S3′; the luminous intensity of the region corresponding to the first reflective layer 22′ in the first type first anode 2′ shown in FIG. 5 is S2, and the luminous intensity corresponding to a region in the first transparent conductive layer 21′ that does not overlap with the first reflective layer 22′ (i.e., transmissive light region) is S3; then S2′+S3′=S2+S3 in order to ensure the uniform luminous brightness of the first display region AA1. Therefore, the sizes of the corresponding first reflective layers and first transparent conductive layers in the first-type first anode 2′ and the second-type first anode 2 are adjusted so that S2′+S3′=S2+S3. Therefore, the disclosure can achieve the uniform luminous brightness of the first display region AA1 on the basis of reducing diffraction, and does not affect the display quality on the basis of improving the photograph quality. In some examples, the ratio of (S2′+S3′) to (S2+S3) may be in a range of 0.7 to 1.5, and even a slight difference in brightness is not easily perceptible to the human eyes.

In a specific implementation, the above display panel provided by an embodiment of the disclosure, as shown in FIGS. 2 and 3, further includes a plurality of second sub-pixels located in the second display region AA2. Each of the second sub-pixels is provided with a second anode 3. As shown in FIG. 7, the second anode 3 includes: a third transparent conductive layer 31 on the substrate 1, a second reflective layer 32 on a side of the third transparent conductive layer 31 away from the substrate 1, and a fourth transparent conductive layer 33 on a side of the second reflective layer 32 away from the substrate 1.

Each film layer of the second anode 3 is formed using an etching process. In theory, the third transparent conductive layer 31, the second reflective layer 32 and the fourth transparent conductive layer 33 of which the orthographic projections are completely overlapped are formed. But in some processes, due to different etching rates of the materials of layers, there may also be structures with incompletely overlapping edges, while this belongs to the process deviation of one etching. Therefore, the orthographic projections of the third transparent conductive layer 31, the second reflective layer 32 and the fourth transparent conductive layer 33 on the substrate 1 substantially overlap.

The third transparent conductive layer 31 and the first transparent conductive layers (21 and 21′) are arranged in the same layer, the second reflective layer 32 and the first reflective layers (22 and 22′) are arranged in the same layer, and the fourth transparent conductive layer 33 and the second transparent conductive layers (23 and 23′) are arranged in the same layer.

In a specific implementation, in the above display panel provided by an embodiment of the disclosure, as shown in FIG. 8, FIG. 8 is a schematic diagram of a part of the first transparent conductive layers (21 and 21′) of the first display region AA1 and a part of the third transparent conductive layer 31 of the second display region AA2, and FIG. 8 schematically shows the first transparent conductive layer corresponding to the first sub-pixel 101 (for example, B), the first transparent conductive layer corresponding to the second sub-pixel 102 (for example, R), and the first transparent conductive layer corresponding to the third sub-pixel 103 (for example, G) in FIG. 2 and FIG. 3. Each of the first transparent conductive layers (21 and 21′) of the first anodes (2 and 2′) includes a main body part 201 and a connection line 202 connected to the main body part 201, and the orthographic projection of the first reflective layer 22′ in the first-type first anode 2′ (not shown in FIG. 8) on the substrate 1 falls into a range of the orthographic projection of the main body portion 201 in the first-type first anode 2′ on the substrate 1, that is, the orthographic projection area of the first reflective layer 22′ on the substrate 1 is smaller than the orthographic projection area of the main body part 201 on the substrate 1. Since the first-type first anode 2′ is formed using the etching process, the middle region of the first-type first anode 2′ can reflect light and the surrounding region thereof transmits light, facilitating the implementation of the etching process.

The display panel includes a driving circuit on the substrate and a light-emitting device on a side of the driving circuit away from the substrate. A flat layer is generally disposed between the driving circuit and the light-emitting device. The driving circuit includes a thin film transistor, and the thin film transistor includes, for example, an active layer, a gate, a source and a drain. The light-emitting device includes an anode, a light-emitting layer and a cathode that are stacked in sequence. The flat layer includes a via hole V, and for example, the first transparent conductive layer (21 and 21′) of the first anode of each light-emitting device in the first display region AA1 is electrically connected to the drain of the driving circuit through the via hole V. The via hole V is filled with the material of the first transparent conductive layer to realize the corresponding electrical connection between the first transparent conductive layer (21 and 21′) and the drain.

Optionally, in the above display panel provided by an embodiment of the disclosure, as shown in FIG. 8, a center position of the first reflective layer 22′ in the first-type first anode 2′ (not shown in FIG. 8) substantially coincides with a center position of the main body part 201, because there may also be structures with incompletely overlapping edges due to different etching rates of the materials of layers, while this belongs to the process deviation of one etching. Since the first reflective layer 22′ and the second transparent conductive layer 23′ are formed using the etching process, the center position of the first reflective layer 22′ in the second-type first anode 2′ substantially coincides with the center position of the first transparent conductive layer 21′ in the second-type first anode 2′, facilitating the implementation of the etching process.

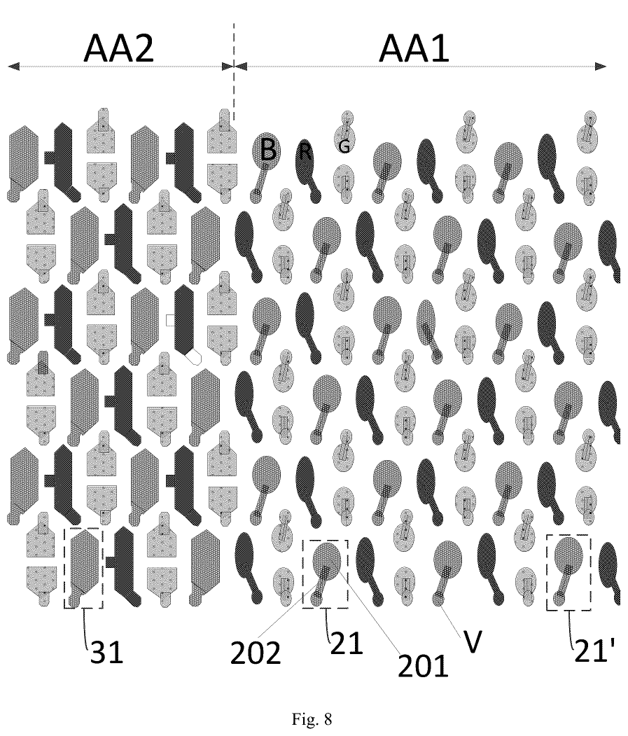

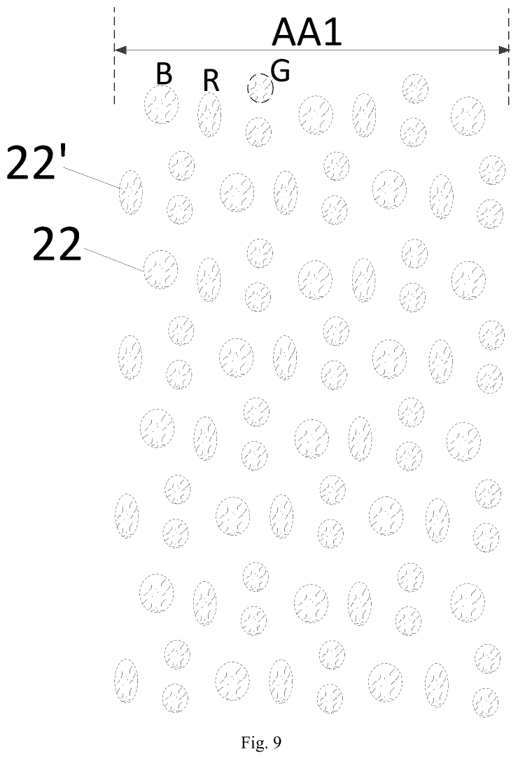

In a specific implementation, in the above-mentioned display panel provided by an embodiment of the disclosure, as shown in FIG. 9, FIG. 9 is a schematic diagram of a theoretical top view of the first reflective layer (22 and 22′) in the first display region AA1. The material of the reflective layer is metallic material such as Ag, but not limited thereto. Referring to FIG. 8, for the positions of the connection line 202 and the connection via hole V, there is only the material of the first transparent conductive layer (21 and 21′), that is, the first reflective layer (22 and 22′) corresponds to the first main body part 201, and there is no Ag or a small amount of residual Ag in the via hole V.

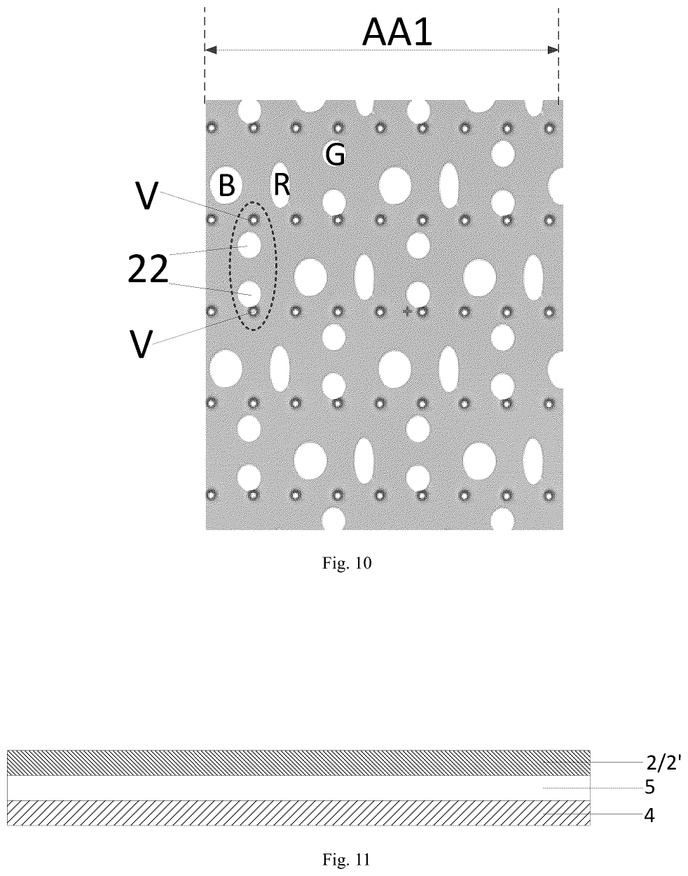

As shown in FIG. 10, FIG. 10 is a schematic diagram of the effect obtained by the actual fabrication of the first reflective layers (22 and 22′) in the first display region AA1, including a schematic diagram of the first reflective layers (for example, 22) corresponding to a red (R) first sub-pixel, a green (G) first sub-pixel and a blue (B) first sub-pixel. The first transparent conductive layer (not shown) is below the first reflective layer 22. The first transparent conductive layer has a main body part similar in shape to the first reflective layer 22, and a connection line connected to the main body part. The end of the connection line far away from the main body part corresponds to a via hole V in the flat layer. The dot pixel arrangement in an embodiment of the disclosure adopts the RBGG pattern, where the distances of the via holes V corresponding to two upper and lower adjacent Gs from the first reflective layers 22 are different, for example, the distance of the upper via hole from the upper first reflective layer 22 is greater than the distance of the lower via hole from the lower first reflective layer 22 as shown in the dotted frame in FIG. 10. Thus the structures of the first anodes (2 and 2′) in the first display region AA1 are different, thereby further destroying the original regularity of the light transmitted through the first display region AA1, so that the phenomenon of strengthened light in some specific directions or points disappears, and the luminous brightness of parts other than the center point is reduced, thereby reducing diffraction, alleviating glare, and increasing the photography quality.

In a specific implementation, in the above display panel provided by an embodiment of the disclosure, as shown in FIG. 2 and FIG. 3, the plurality of first anodes include a plurality of first-type first anodes 2′, and the plurality of first anodes include a plurality of second-type first anodes 2. For the convenience of manufacture, all the first-type first anodes 2′ and all the second-type first anodes 2 may be uniformly distributed in the first display region AA1. Of course, all the first-type first anodes 2′ and all the second-type first anodes 2 may also be randomly distributed in the first display region AA1, which can destroy the original regularity of the light transmitted through the first display region AA1, so that the phenomenon of strengthened light in some specific directions or points disappears, and the luminous brightness of parts other than the center point is reduced, thereby reducing diffraction, alleviating glare, and increasing the photography quality.

In a specific implementation, in the above display panel provided by an embodiment of the disclosure, as shown in FIGS. 2 and 3, the plurality of first anodes (2 and 2′) in the first display region AA1 are distributed in an array. As shown in FIG. 2, the first-type first anodes 2′ and the second-type first anodes 2 are alternately arranged in a column direction, or as shown in FIG. 3, the first-type first anodes 2′ and the second-type first anodes 2 are alternately arranged in a row direction.

It should be noted that the first-type first anode 2′ and the second-type first anode 2 shown in FIG. 2 provided by an embodiment of the disclosure are arranged at an interval of one row, and of course may be arranged at an interval of two or more rows. The first-type first anode 2′ and the second-type first anode 2 shown in FIG. 3 provided by an embodiment of the disclosure are arranged at an interval of one column, and of course may be arranged at an interval of two or more columns.

It should be noted that the closest distance between the first-type first anode 2′ and the second-type first anode 2 provided by an embodiment of the disclosure is the width of a row of sub-pixels or the width of a column of sub-pixels, and the closest distance needs to be selected according to the actual size of the sub-pixels.

In a specific implementation, in the above display panel provided by an embodiment of the disclosure, as shown in FIG. 2 and FIG. 3, the plurality of first sub-pixels have a plurality of emission colors, for example, the first sub-pixels include three emission colors. In an embodiment of the disclosure, the red (R) first sub-pixel, the green (G) first sub-pixel and the blue (B) first sub-pixel are taken as an example, but the disclosure is not limited thereto. The first-type first anode 2′ and the second-type first anode 2 correspond to the first sub-pixels with the same emission color. For example, the first display region AA1 includes a red (R) first sub-pixel, a green (G) first sub-pixel and a blue (B) first sub-pixel. The red (R) first sub-pixel may be provided with a first-type first anode 2′ and a second-type first anode 2, or the green (G) first sub-pixel may be provided with a first-type first anode 2′ and a second-type first anode 2, or the blue (B) first sub-pixel may be provided with a first-type first anode 2′ and a second-type first anode 2.

In a specific implementation, the above display panel provided by an embodiment of the disclosure, as shown in FIG. 3, further includes a plurality of second sub-pixels located in the second display region AA2. Each of the second sub-pixels is provided with a second anode 3. As shown in FIG. 7, the second anode 3 includes: a third transparent conductive layer 31 on the substrate 1, a second reflective layer 32 on a side of the third transparent conductive layer 31 away from the substrate 1, and a fourth transparent conductive layer 33 on a side of the second reflective layer away 32 from the substrate 1. As shown in FIGS. 3 and 7, a resolution of the first display region AA1 is less than a resolution of the second display region AA2, and a ratio of an area of the second reflective layer 32 in the second anode 3 to an area of the first reflective layer 21 in the first anode 2 may be in a range of 0.7 to 1.5. In this way, the transmittance of the first display region AA1 may be greater than that of the second display region AA2, so as to realize the camera under panel technology.

In a specific implementation, the above display panel provided by an embodiment of the disclosure, as shown in FIG. 2, further includes a plurality of second sub-pixels located in the second display region AA2. Each of the second sub-pixels is provided with a second anode 3. As shown in FIG. 7, the second anode 3 includes: a third transparent conductive layer 31 on the substrate 1, a second reflective layer 32 on a side of the third transparent conductive layer 31 away from the substrate 1, and a fourth transparent conductive layer 33 on a side of the second reflective layer 32 away from the substrate 1. As shown in FIGS. 2 and 7, a ratio of a resolution of the first display region AA1 to a resolution of the second display region AA2 may be in a range of 0.8 to 1.2, and the second anode 3 is larger than the first anode 2 in size, so that the transmittance of the first display region AA1 is greater than that of the second display region AA2, so as to realize the camera under panel technology. Also, the structure shown in FIG. 2 can reach the effect that the display region of the camera under panel (i.e., the first display region AA1) can display images with the same pixel resolution as the second display region AA2 and improve the luminous brightness of the display region of the camera under panel, reducing the brightness difference between the main display region (i.e., the second display region AA2) and the display region of the camera under panel (i.e., the first display region AA1).

In a specific implementation, the above display panel provided by an embodiment of the disclosure, as shown in FIGS. 2 and 3, further includes a bezel region BB located outside the display region AA, and further includes a plurality of first driving circuits (not shown) electrically connected to the first anodes (2 and 2′). The plurality of first driving circuits are located in the bezel region BB adjacent to the first display region AA1. Thus, the light transmittance of the first display region AA1 can be increased, so that the first display region AA1 is used as the region where the camera is placed, facilitating the implementation of the full screen. Alternatively, the second display region AA2 has a transition region CC adjacent to the first display region AA1, and the plurality of first driving circuits are located in the transition region CC, or the plurality of first driving circuits are distributed in the second display region AA2.

In a specific implementation, since the first driving circuits are electrically connected to the light-emitting devices in the first display region AA1 through transparent wires, the disclosure can reduce the length of the transparent wires between the first driving circuits and the light-emitting devices in the first display region AA1 effectively by arranging the plurality of first driving circuits in the bezel region BB adjacent to the first display region AA1 or in the transition region CC adjacent to the first display region AA1, thereby reducing the resistance of the transparent wires and improving the long-range uniformity of driving signals.

In a specific implementation, the above display panel provided by an embodiment of the disclosure, as shown in FIG. 11, further includes a transparent wire routing layer 5 between the first driving circuits 4 and the first anodes (2 and 2′). The first driving circuits 4 are electrically connected to the first anodes (2 and 2′) through transparent wires in the transparent wire routing layer 5.

The transparent wire routing layer may be a plurality of layers. The layers are insulated from each other, and each transparent wire routing layer includes a plurality of transparent wires.

Optionally, in the above display panel provided by an embodiment of the disclosure, a plurality of transparent wires contained in each transparent wire routing layer do not overlap with each other, and orthographic projections of a plurality of transparent wires contained in different transparent wire routing layers on the base substrate do not overlap with each other. Of course, since different transparent wire routing layers are insulated from each other, the orthographic projections of the plurality of transparent wires contained in the different transparent wire routing layers on the substrate may also partially overlap or completely overlap in a specific implementation, which is not limited here.

Optionally, in the above display panel provided by an embodiment of the disclosure, the material of the transparent wire routing layer may be ITO.

In a specific implementation, in the above display panel provided by an embodiment of the disclosure, as shown in FIGS. 4-7, the materials of the first transparent conductive layers (21 and 21′), the second transparent conductive layers (23 and 23′), the third transparent conductive layer 31 and the fourth transparent conductive layer 34 may include but are not limited to at least one of ITO, IZO or IGZO, and the materials of the first reflective layers (22 and 22′) and the second reflective layer 23 may include but are not limited to at least one of Al, Ag, Mo, Ti or TiN.

It should be noted that the shape of the first display region AA1 in the disclosure may be a rectangle as shown in FIG. 2 and FIG. 3, or may be other shape such as a circle, an ellipse or a polygon, which can be designed according to actual requirements and is not limited here. The second display region AA2 may surround the periphery of the first display region AA1 as shown in FIG. 2 and FIG. 3, or may surround a part of the first display region AA1, for example, surround the left side, the lower side and the right side of the first display region AA1, while the upper boundary of the first display region AA1 is coincident with the upper boundary of the second display region AA2.

Optionally, in the above display panel provided by an embodiment of the disclosure, as shown in FIG. 2 and FIG. 3, the first display region AA1 is configured to install a photosensitive device, such as a camera module. Since there are only light-emitting devices in the first display region AA1 in the disclosure, a larger light-transmitting region can be provided, facilitating to adapt to a larger-sized camera module.

It should be noted that the first display region AA1 in embodiments of the disclosure is not limited to installing the camera module, and may also install a fingerprint recognition module. In embodiments of the disclosure, FIG. 2 and FIG. 3 take the first display region AA1 located above the display panel as an example for illustration. The first display region AA1 located above the display panel is generally used for installing the camera module. Fingerprint recognition generally includes finger fingerprint recognition and face recognition. When the finger fingerprint recognition is used, the first display region AA1 occupies a small part of the display region AA and is located below the display panel. When the face recognition is used, the entire display region AA can be provided with a fingerprint recognition module, so that the entire display region AA includes a first-type first anode 2′ and a second-type first anode 2, that is, the entire display region AA uses the anode structure of the first display region AA1 introduced above in embodiments of the disclosure, which will not be repeated here.

The simulation result that the display panels shown in FIGS. 2 and 3 provided in the related art and in embodiments of the disclosure can enhance the anti-glare effect will be illustrated below.

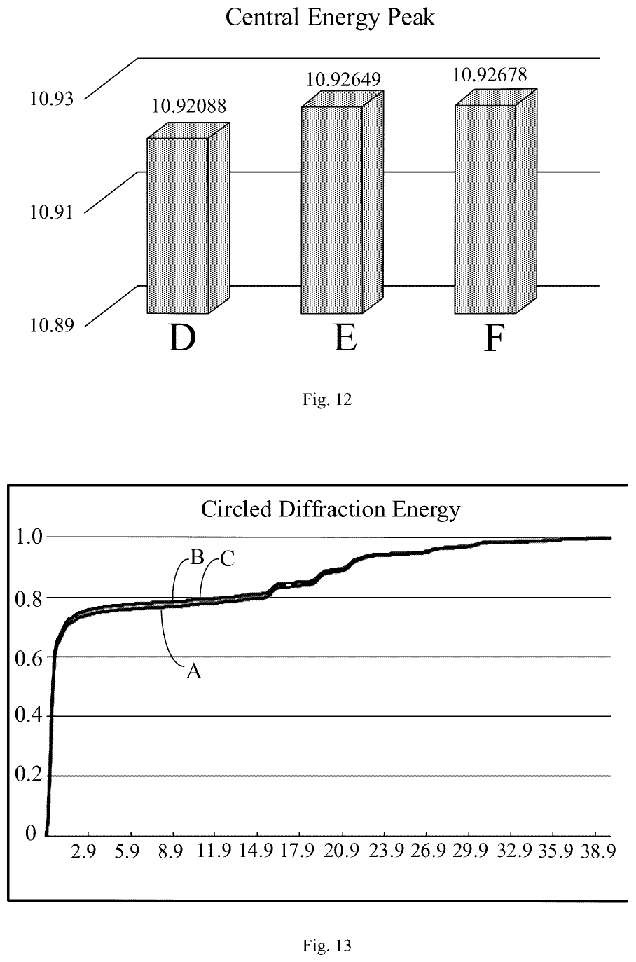

As shown in FIGS. 2 and 3, the central energy peak corresponding to the sub-pixel emission corresponding to the first anodes (2 and 2′) in the central region of the first display region AA1 in FIG. 2 and FIG. 3 is selected. As shown in FIG. 12, the first bar graph from the left in FIG. 12 is the central energy peak (represented by D) of the emission of the central region in the first display region in the related art, the second bar graph from the left is the central energy peak (represented by E) of the emission of the central region in the first display region AA1 of FIG. 2, and the third bar graph from the left is the central energy peak (represented by F) of the emission of the central region in the first display region AA1 of FIG. 3. It can be seen that the central energy peaks corresponding to FIGS. 2 and 3 are greater than the central energy peak measured in the related art, so the scheme of embodiments of the disclosure can reduce the luminous intensity outside the central area, thereby reducing the diffraction and improving the photograph quality.

In an embodiment of the disclosure, the circled diffraction energy of the emission of sub-pixels in the range of 0-40 μm is selected in the first display region AA1 of the display panel provided in the related art and embodiments of the disclosure to perform a simulation test. As shown in FIG. 13, the curve A represents the simulation structure in the related art, the curve B is the simulation result shown in FIG. 2, and the curve C is the simulation result shown in FIG. 3. It can be seen that the simulation results (circled diffraction energy) shown in FIG. 2 and FIG. 3 are almost the same, and both are larger than the circled diffraction energy in the related art. Therefore, it is further verified that the scheme of embodiments of the disclosure can reduce the luminous intensity outside the central area, thereby reducing the diffraction and improving the photograph quality.

Based on the same inventive concept, an embodiment of the disclosure further provides a manufacturing method of a display panel, including: providing a substrate; where the substrate has a display region, the display region including a first display region and a second display region; the substrate has a plurality of first sub-pixels located in the first display region; where light transmittance of the first display region is greater than light transmittance of the second display region; forming a plurality of first anodes in the first sub-pixels of the substrate; where each of the first anodes includes: a first transparent conductive layer on the substrate, a first reflective layer on a side of the first transparent conductive layer away from the substrate, and a second transparent conductive layer on a side of the first reflective layer away from the substrate; where the plurality of first anodes include at least one first-type first anode, and an orthographic projection area of a first transparent conductive layer in the first-type first anode on the substrate is larger than an orthographic projection area of a first reflective layer in the first-type first anode on the substrate.

In the above manufacturing method of the display panel provided by an embodiment of the disclosure, at least one first-type first anode is arranged in the first display region (i.e., the position where the camera is placed), and the area of the reflective layer in the first-type the first anode is set to be smaller than the area of the first transparent conductive layer, that is, the first-type first anode has a reflective light region and a transmissive light region, so that the first anodes in the first display region may be set to be different structures, so the anodes with different structures in the first display region correspond to different light-emitting forms, and the center points and brightness distributions of the light-emitting formations are also different. Therefore, the arrangement of the first-type first anode in the first display region can destroy the regularity of the light transmitted through the first display region, so that the phenomenon of strengthened light in some specific directions or points disappears, and the luminous brightness of parts other than the center point is reduced, thereby reducing diffraction, alleviating glare, and increasing the photography quality.

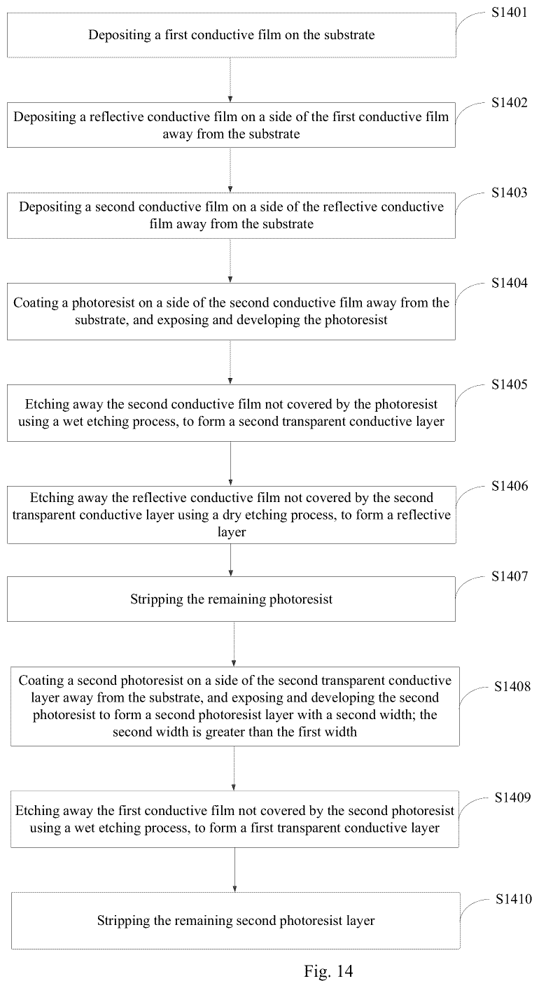

In a specific implementation, in the above manufacturing method provided by an embodiment of the disclosure, forming the first-type first anode in a first sub-pixel of the substrate, as shown in FIG. 14, may include following steps.

S1401: depositing a first conductive film on the substrate. A material of the first conductive film includes at least one of ITO, IZO or IGZO.

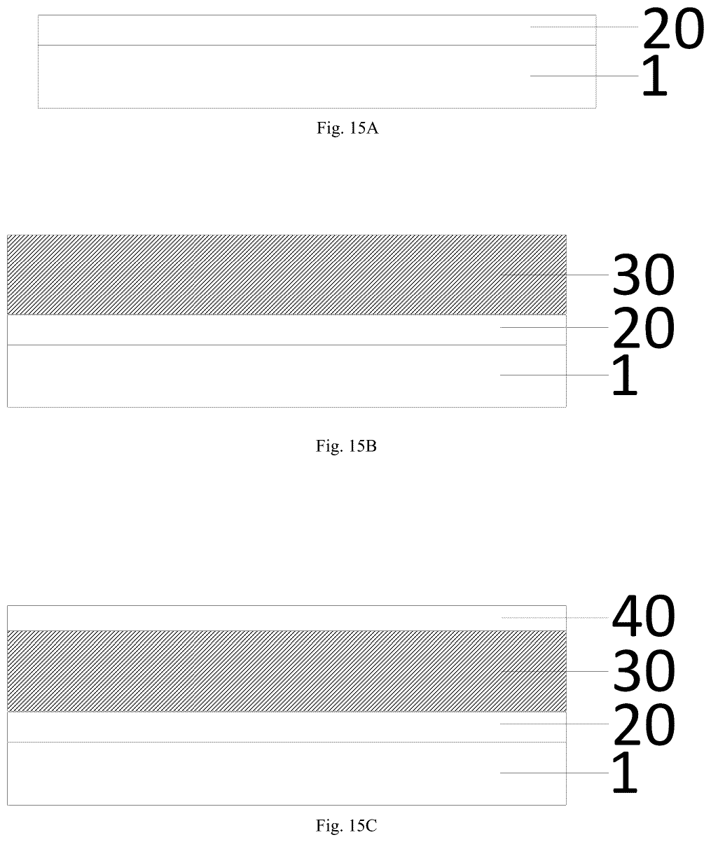

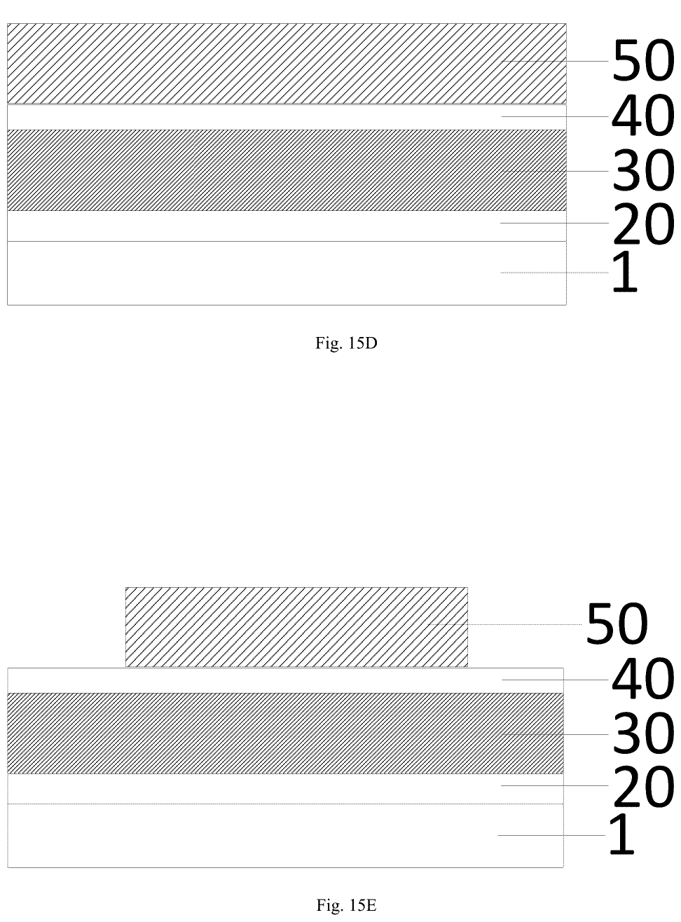

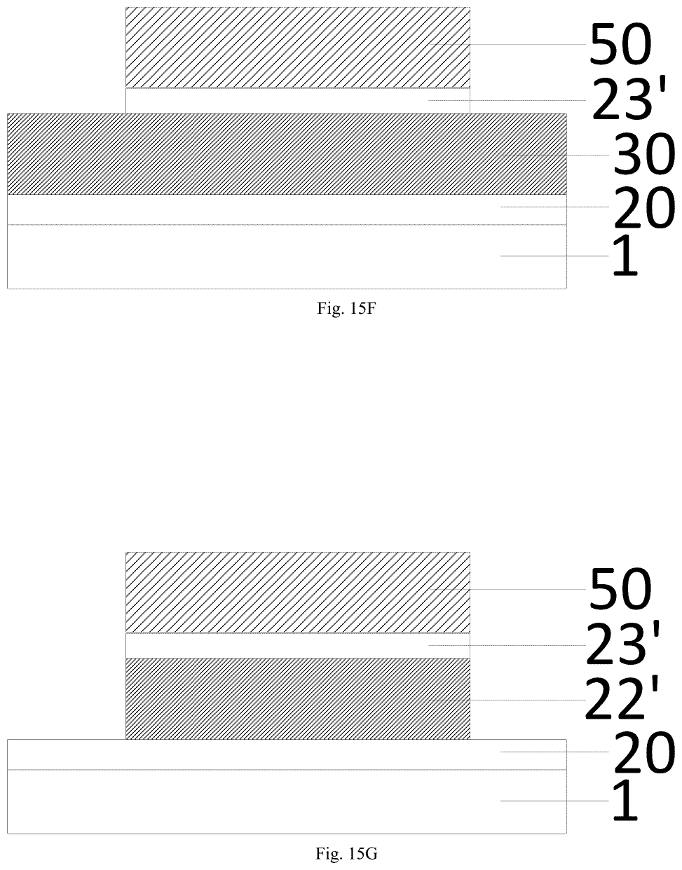

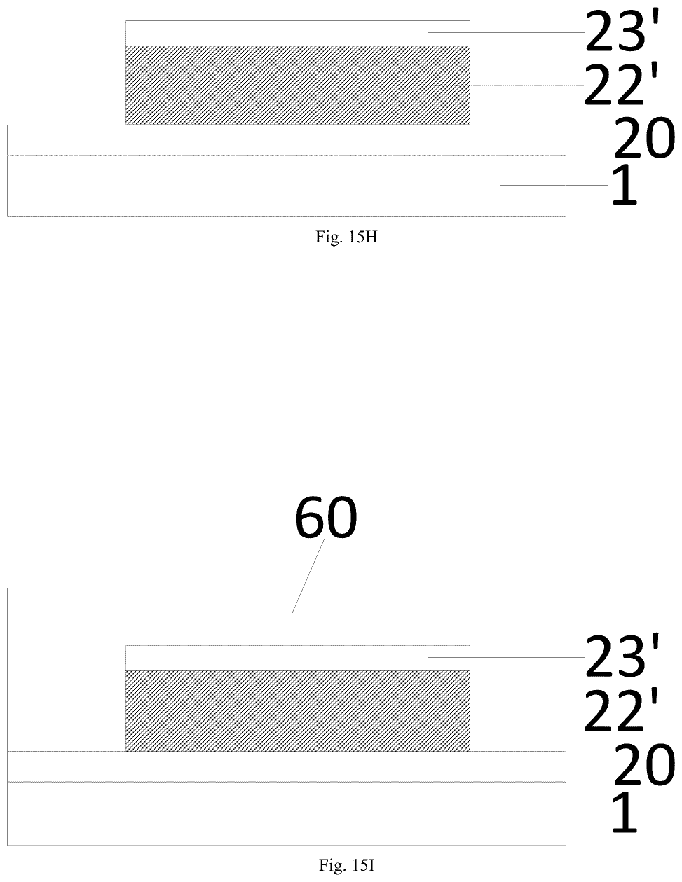

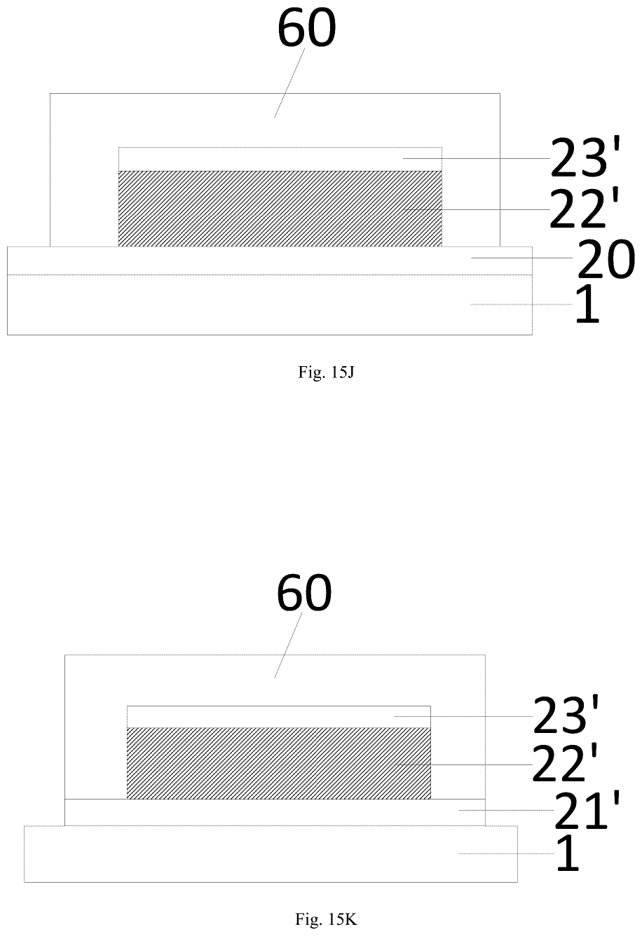

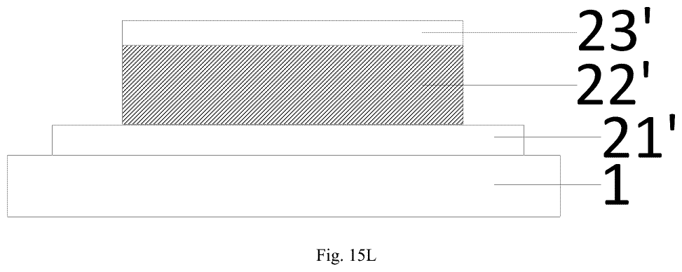

As shown in FIG. 15A, the first conductive thin film 20 is deposited on the substrate 1.

S1402: depositing a reflective conductive film on a side of the first conductive film away from the substrate. A material of the reflective conductive film includes at least one of Al, Ag, Mo, Ti or TiN.

As shown in FIG. 15B, the reflective conductive film 30 is deposited on the side of the first conductive film 20 away from the substrate 1.

S1403: depositing a second conductive film on a side of the reflective conductive film away from the substrate. A material of the second conductive film includes at least one of ITO, IZO or IGZO.

As shown in FIG. 15C, the second conductive film 40 is deposited on the side of the reflective conductive film 30 away from the substrate 1.

S1404: coating a first photoresist on a side of the second conductive film away from the substrate, and exposing and developing the first photoresist to form a first photoresist layer with a first width.

As shown in FIG. 15D, the first photoresist 50 is coated on the side of the second conductive film 40 away from the substrate 1. As shown in FIG. 15E, the first photoresist 50 is exposed and developed to form the first photoresist layer 50 with the first width.

S1405: etching away the second conductive film not covered by the first photoresist using a wet etching process, to form a second transparent conductive layer.

As shown in FIG. 15F, the second conductive film 40 not covered by the first photoresist 50 is etched away using the wet etching process, to form the second transparent conductive layer 23′.

S1406: etching away the reflective conductive film not covered by the second transparent conductive layer using a dry etching process, to form a first reflective layer.

As shown in FIG. 15G, the reflective conductive film 30 not covered by the second transparent conductive layer 23′ is etched away using the dry etching process, to form the first reflective layer 22′.

S1407: stripping the remaining first photoresist.

As shown in FIG. 15H, the remaining first photoresist 50 is stripped.

S1408: coating a second photoresist on a side of the second transparent conductive layer away from the substrate, and exposing and developing the second photoresist to form a second photoresist layer with a second width. The second width is greater than the first width.

As shown in FIG. 15I, the second photoresist 60 is coated on the side of the second transparent conductive layer 23′ away from the substrate 1. As shown in FIG. 15J, the second photoresist 60 is exposed and developed to form the second photoresist layer 60 with the second width.

S1409: etching away the first conductive film not covered by the second photoresist using a wet etching process, to form a first transparent conductive layer.

As shown in FIG. 15K, the first conductive film 20 not covered by the second photoresist 60 is etched away using the wet etching process, to form the first transparent conductive layer 21′.

S1410: stripping the remaining second photoresist layer.

As shown in FIG. 15L, the remaining second photoresist layer 60 is stripped, forming a first-type first anode 2′ in a first sub-pixel of the substrate 1.

It should be noted that the above manufacturing method of the display panel provided by an embodiment of the disclosure only describes the manufacturing method of the first-type first anode 2′ in detail, and the manufacturing method of other film structures in the display panel is the same as that in the related art, which will not be described in detail here.

Based on the same inventive concept, an embodiment of the disclosure further provides a display apparatus, including a photosensitive device (e.g., a camera module) and the above display panel. The photosensitive device is disposed in the first display region of the display panel. Optionally, the photosensitive device may be a camera module.

The display apparatus may be: a mobile phone, a tablet computer, a television, a display, a notebook computer, a digital photo frame, a navigator, a smart watch, a fitness wristband, a personal digital assistant, and any other product or component with display function. All of other indispensable components of the display apparatus should be understood by those ordinary skilled in the art to be included, and will be omitted here and should not be considered as limitations on the disclosure. In addition, since the principle of the display apparatus to solve the problem is similar to the principle of the above-mentioned display panel to solve the problem, the implementations of the display apparatus can refer to embodiments of the above-mentioned display panel, and the repeated description thereof will be omitted.

In the display panel and the manufacturing method thereof and the display apparatus provided by embodiments of the disclosure, at least one first-type first anode is arranged in the first display region (i.e., the position where the camera is placed), and the area of the reflective layer in the first-type the first anode is set to be smaller than the area of the first transparent conductive layer, that is, the first-type first anode has a reflective light region and a transmissive light region, so that the first anodes in the first display region may be set to be different structures, so the anodes with different structures in the first display region correspond to different light-emitting forms, and the center points and brightness distributions of the light-emitting formations are also different. Therefore, the arrangement of the first-type first anode in the first display region can destroy the regularity of the light transmitted through the first display region, so that the phenomenon of strengthened light in some specific directions or points disappears, and the luminous brightness of parts other than the center point is reduced, thereby reducing diffraction, alleviating glare, and increasing the photography quality.

Although embodiments of the disclosure have been described, those skilled in the art can make additional alterations and modifications to these embodiments once they learn about the basic creative concepts. Thus the attached claims are intended to be interpreted to include embodiments as well as all the alterations and modifications falling within the scope of the disclosure.

Evidently those skilled in the art can make various modifications and variations to embodiments of the disclosure without departing from the spirit and scope of embodiments of the disclosure. Thus the disclosure is also intended to encompass these modifications and variations to embodiments of the disclosure as long as these modifications and variations come into the scope of the claims of the disclosure and their equivalents.

1. A display panel having a display region, the display region comprising: a first display region and a second display region; wherein light transmittance of the first display region is greater than light transmittance of the second display region; and the display panel comprises:
a substrate having a plurality of first sub-pixels located in the first display region;
the plurality of first sub-pixels comprise a plurality of first anodes, and each of the first anodes comprises: a first transparent conductive layer on the substrate, a first reflective layer on a side of the first transparent conductive layer away from the substrate, and a second transparent conductive layer on a side of the first reflective layer away from the substrate; wherein:
the plurality of first anodes comprise at least one first-type first anode, and an orthographic projection area of a first transparent conductive layer in the first-type first anode on the substrate is larger than an orthographic projection area of a first reflective layer in the first-type first anode on the substrate.

2. The display panel of claim 1, wherein orthographic projections of the first reflective layer and a second transparent conductive layer in the first-type first anode on the substrate substantially overlap.

3. The display panel of claim 1, wherein the plurality of first anodes further comprises a second-type first anode, and an orthographic projection area of a first transparent conductive layer in the second-type first anode on the substrate is larger than an orthographic projection area of a first reflective layer in the second-type first anode on the substrate;
the first transparent conductive layer and the first reflective layer in the first-type first anode have a first non-overlapping region, the first transparent conductive layer and the first reflective layer in the second-type first anode have a second non-overlapping region, and an area of the first non-overlapping region is different from an area of the second non-overlapping region.

4. The display panel of claim 3, wherein the area of the first non-overlapping region is larger than the area of the second non-overlapping region, and an area of the first reflective layer in the first-type first anode is smaller than an area of the first reflective layer in the second-type first anode.

5. The display panel of claim 3, wherein the area of the first non-overlapping region is smaller than the area of the second non-overlapping region, and an area of the first reflective layer in the first-type first anode is larger than an area of the first reflective layer in the second-type first anode.

6. The display panel of claim 1, wherein the plurality of first anodes further comprises a second-type first anode, and orthographic projections of a first transparent conductive layer, a first reflective layer and a second transparent conductive layer in the second-type first anode on the substrate substantially overlap;
wherein an orthographic projection area of the first transparent conductive layer in the first-type first anode on the substrate is larger than an orthographic projection area of the first transparent conductive layer in the second-type first anode on the substrate, and an orthographic projection area of the first reflective layer in the second-type first anode on the substrate is larger than an orthographic projection area of the first reflective layer in the first-type first anode on the substrate.

7. (canceled)

8. The display panel of claim 1, wherein the first transparent conductive layer of the first anode comprises a main body part and a connection line connected to the main body part, and an orthographic projection of the first reflective layer in the first-type first anode on the substrate falls into a range of an orthographic projection of a main body part in the first-type first anode on the substrate;
wherein a center position of the first reflective layer in the first-type first anode substantially coincides with a center position of the main body part.

9. (canceled)

10. The display panel of claim 3, wherein the plurality of first anodes comprise a plurality of first-type first anodes, the plurality of first anodes comprise a plurality of second-type first anodes, and all the first-type first anodes and all the second-type first anodes are uniformly distributed in the first display region.

11. The display panel of claim 10, wherein the plurality of first anodes are distributed in an array, the first-type first anodes and the second-type first anodes are alternately arranged in a column direction, or the first-type first anodes and the second-type first anodes are alternately arranged in a row direction.

12. The display panel of claim 3, further comprising a plurality of second sub-pixels located in the second display region, wherein each of the second sub-pixels is provided with a second anode, the second anode comprises: a third transparent conductive layer on the substrate, a second reflective layer on a side of the third transparent conductive layer away from the substrate, and a fourth transparent conductive layer on a side of the second reflective layer away from the substrate;
orthographic projections of the third transparent conductive layer, the second reflective layer and the fourth transparent conductive layer on the substrate substantially overlap.

13. The display panel of claim 3, wherein the plurality of first sub-pixels have a plurality of emission colors, and the first-type first anode and the second-type first anode correspond to first sub-pixels with a same emission color.

14. The display panel of claim 1, further comprising a plurality of second sub-pixels located in the second display region, wherein each of the second sub-pixels is provided with a second anode, the second anode comprises: a third transparent conductive layer on the substrate, a second reflective layer on a side of the third transparent conductive layer away from the substrate, and a fourth transparent conductive layer on a side of the second reflective layer away from the substrate; a resolution of the first display region is less than a resolution of the second display region, and a ratio of an area of the second reflective layer in the second anode to an area of the first reflective layer in the first anode is in a range of 0.7 to 1.5.

15. The display panel of claim 1, further comprising a plurality of second sub-pixels located in the second display region, wherein each of the second sub-pixels is provided with a second anode, the second anode comprises: a third transparent conductive layer on the substrate, a second reflective layer on a side of the third transparent conductive layer away from the substrate, and a fourth transparent conductive layer on a side of the second reflective layer away from the substrate; a ratio of a resolution of the first display region to a resolution of the second display region is in a range of 0.8 to 1.2, and the second anode is larger than the first anode in size.

16. The display panel of claim 1, further comprising a bezel region located outside the display region, and the display panel further comprising a plurality of first driving circuits electrically connected to the first anodes, wherein the plurality of first driving circuits are located in the bezel region adjacent to the first display region; or
the second display region has a transition region adjacent to the first display region, and the plurality of first driving circuits are located in the transition region, or the plurality of first driving circuits are distributed in the second display region.

17. The display panel of claim 16, further comprising a transparent wire routing layer between the first driving circuits and the first anodes, wherein the first driving circuits are electrically connected to the first anodes through transparent wires in the transparent wire routing layer.

18. The display panel of claim 12, wherein materials of the first transparent conductive layer, the second transparent conductive layer, the third transparent conductive layer and the fourth transparent conductive layer comprise at least one of ITO, IZO or IGZO, and materials of the first reflective layer and the second reflective layer comprise at least one of Al, Ag, Mo, Ti or TiN.

19. The display panel of claim 1, wherein a shape of the first display region is at least one of a circle, an ellipse, a rectangle or a polygon.

20. A display apparatus, comprising a photosensitive device and the display panel according to claim 1; wherein the photosensitive device is disposed in the first display region of the display panel.

21. A manufacturing method of a display panel, comprising:
providing a substrate; wherein the substrate has a display region, the display region comprises a first display region and a second display region; the substrate has a plurality of first sub-pixels located in the first display region; wherein light transmittance of the first display region is greater than light transmittance of the second display region;
forming a plurality of first anodes in the first sub-pixels of the substrate; wherein each of the first anodes comprises: a first transparent conductive layer on the substrate, a first reflective layer on a side of the first transparent conductive layer away from the substrate, and a second transparent conductive layer on a side of the first reflective layer away from the substrate; wherein:
the plurality of first anodes comprise at least one first-type first anode, and an orthographic projection area of a first transparent conductive layer in the first-type first anode on the substrate is larger than an orthographic projection area of a first reflective layer in the first-type first anode on the substrate.

22. The manufacturing method of claim 21, wherein forming the first-type first anode in a first sub-pixel of the substrate, comprises:
depositing a first conductive film on the substrate; wherein a material of the first conductive film comprises at least one of ITO, IZO or IGZO;
depositing a reflective conductive film on a side of the first conductive film away from the substrate; wherein a material of the reflective conductive film comprises at least one of Al, Ag, Mo, Ti or TiN;
depositing a second conductive film on a side of the reflective conductive film away from the substrate; wherein a material of the second conductive film comprises at least one of ITO, IZO or IGZO;
coating a first photoresist on a side of the second conductive film away from the substrate, and exposing and developing the first photoresist to form a first photoresist layer with a first width;
etching away the second conductive film not covered by the first photoresist using a wet etching process, to form a second transparent conductive layer;
etching away the reflective conductive film not covered by the second transparent conductive layer using a dry etching process, to form a first reflective layer;
stripping the remaining first photoresist layer;
coating a second photoresist on a side of the second transparent conductive layer away from the substrate, and exposing and developing the second photoresist to form a second photoresist layer with a second width; wherein the second width is greater than the first width;
etching away the first conductive film not covered by the second photoresist using a wet etching process, to form a first transparent conductive layer;
stripping the remaining second photoresist layer.
